(19) United States
(12) Patent Application Publication
(10) Pub. No.: US 2002/0062791 A1
(43) Pub. Date: May 30, 2002

(54) Table

(76) Inventors: Andrey Ginovker, Mississauga (CA); Leonid Druker, Willowdale (CA); Darek Molenda, Caledon (CA); Mariusz Warzyszynski, Mississauga (CA)

Correspondence Address: EUGENE J A GIERZAK, KEYSER MASON BALL, 201 CITY CENTRE DRIVE, SUITE 701, MISSISSAUGA, ONTARIO, L5B 2T4, CA

(21) Appl. No.: 09/973,846

(22) Filed: Oct. 11, 2001

Related U.S. Application Data
(60) Provisional application No. 60/239,126, filed on Oct. 11, 2000.

(51) Int. Cl. C23C 16/00

(52) U.S. Cl. 118/728; 156/345.51

(57) ABSTRACT

Structure for disposing a material to be treated at an acute angle relative to the axis of rotation so as to permit the substrate to rotate relative to said structure.

### FIELD OF INVENTION

This invention relates generally to vacuum deposition coating and in particular relates to a rotating table for vacuum deposition apparatus and method therefore.

### BACKGROUND ART

A number of methods have been developed for depositing materials, generally metals, in the form of particles or ions unto a target surface to form an adherent, uniform coating. Such methods include thermo deposition, cathode sputtering and chemical vapour deposition.

These techniques are usually conducted in a vacuum chamber having a cathode source, an anode source, a table or platen for supporting the substrate to be coated.

Generally speaking it is desirable to uniformly coat substrate material.

It is not always possible to uniformly coat the substrate material even if the substrate material is of a uniform configuration. The problem of uniformly coating the substrate material is further exasperated if the substrate material is irregular in shape as the coating material is not always uniformly distributed along or within the substrate material.

Accordingly various apparatus and methods have heretofore been devised in order to enhance the uniformity of the coated material. For example rotating tables or platens are utilized which are rotated within the vacuum chamber in an attempt to more uniformly coat the substrate.

Moreover other devices and method of the prior art dealt with adhesive strength and hardness of the adherent coated layer such as U.S. Pat. No. 6,241,431B1 which teaches a first tool having a coating on the basic body of the tool which has high adhesive strength, but not high hardness, and a second tool of high hardness for the hard material coating where the adhesive strength is not important.

U.S. Pat. No. 4,485,759 shows a substrate support apparatus for rotatebly supporting substrates being coated within an evacuated Physical Vapour Deposition chamber.

Furthermore Balzers Tool Coating Inc. from North Tanawanda, N.Y. has devised a rotating table having a plurality of rotating tool or substrate holders each of which independently rotate relative to one another and relative to the rotating table. Such rotating tool holder is generally massive in size and can approach a weight of 200 kg or more plus the weight of the substrate materials. Furthermore a great number of gears or other rotatable means including bearings and bushings are utilized which presents a very complicated, massive piece of apparatus that must be cleaned and maintained. Such rotating tables also become coated over time with the coating materials. Furthermore the massive weight of the rotating table must also be heated which adds to energy costs as well as the necessity for more complicated means of maintaining a uniform temperature within the vacuum chamber. Such gears and bushings tend to seize up if exposed to elevated temperatures.

It is an object of this invention to provide an improved tool holder which is simpler to construct and easier to maintain.

It is a further object of this invention to provide for tools having coating with improved adhesive strength and hardness characteristics.

It is an object of this invention to provide a multiaxial positive satellite movement without any mechanism.

It is a further object of this invention to provide a tool holder for plasma deposition at elevated temperatures with enhanced capacity and reliability.

### DISCLOSURE OF INVENTION

It is an aspect of this invention to provide means for disposing a material to be coated at an acute angle relative to the axis of rotation so as to permit the tool to rotate relative to said means.

It is a further aspect of this invention to provide a tool holder or substrate holder adapted to be supported on a rotatable table in a vacuum chamber, said tool holder including means for receiving material to be coated at an acute angle relative to the axis of rotation of said table and for relative rotational movement of said tools relative said means.

It is yet another aspect of this invention to provide a plurality of tool holders each comprising a stem with spaced apart discs, each disc having a plurality of holes adapted for receiving a plurality of tools at an acute angle for relative rotational movement there between.

### BRIEF DESCRIPTION OF DRAWINGS

FIG. 1 is a schematic view of one embodiment of the invention.

FIG. 2 Is a kinematic representation of rotational speed formula taken along the line 2a of FIG. 1

FIG. 2(a) is a diagram for explanation of physical principle of invention.

FIG. 3 is a front elevational view of another embodiment of the invention.

FIG. 4 is a front elevational view of another embodiment of the invention.

FIG. 5 is a front elevational view of another embodiment of the invention.

FIG. 6 is a front elevational view of another embodiment of the invention.

FIGS. 7(a), (b), and (c) are front elevational views of other embodiments of the invention.

FIG. 8(a) is a schematic view of another embodiment of the invention where each of the tool holders are disposed along a common radius from the axis but lean towards one another at an acute angle.

FIG. 8(b) is a representative view of FIG. 8(a).

FIG. 8(c) if representative operational view of FIG. 6(a).

FIG. 9 is a schematic view of another embodiment of the invention.

FIG. 10 is a schematic view of another embodiment of the invention.

FIG. 11 is a schematic view of another embodiment of the invention.

FIG. 12 is a schematic view of another embodiment of the invention. particularly for small tools.

FIG. 13(a) is another embodiment of the invention particularly for holding tool inserts having holes therethrough.

FIG. 13(b) is a partial detailed view of FIG. 13(a).

FIG. 13(c) is yet another embodiment of the invention particularly for holding tool inserts having holes therethrough.

FIG. 13(d) is still yet another embodiment of the invention particularly for holding tool inserts having holes therethrough.

FIG. 14 is a partially sectional perspective view of the embodiment shown in FIG. 8(a) and represented in FIG. 8(b).

FIG. 15 is a partial sectional side view of FIG. 14.

FIG. 16 is a perspective view of the carrier plate of FIG. 14.

FIG. 17 is a perspective view of a satellite plate of FIG. 14.

FIG. 18 is a perspective view of FIG. 13(c).

FIG. 19 is a cross-sectional view about the shaft rotating means of FIG. 14.

FIG. 20 is a comparative diagram of the heat management advantages of the invention verses the prior art.

### BEST MODE FOR CARRYING OUT THE INVENTION

In the description that follows, like parts are marked throughout the specification and the drawings with the same respective reference numerals. The drawings are not necessarily to scale and in some instances proportions may have been exaggerated in order to more clearly depict certain features of the invention.

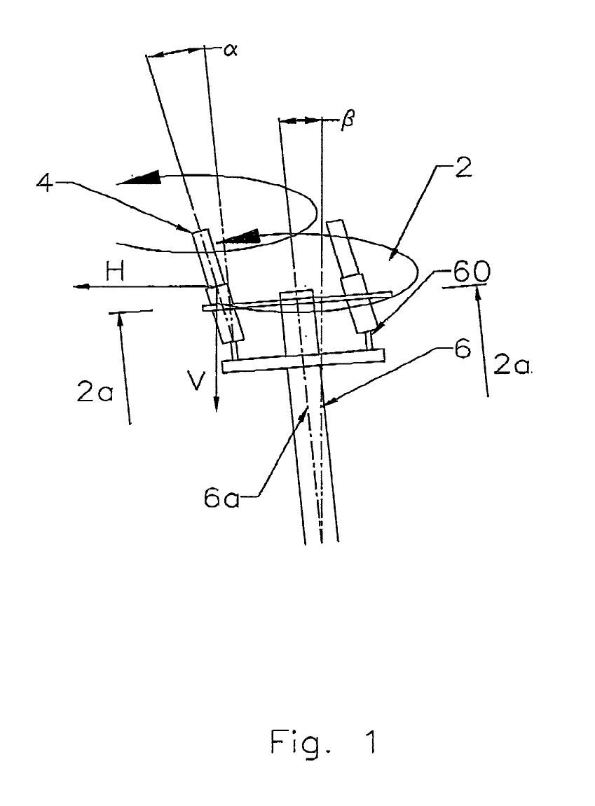

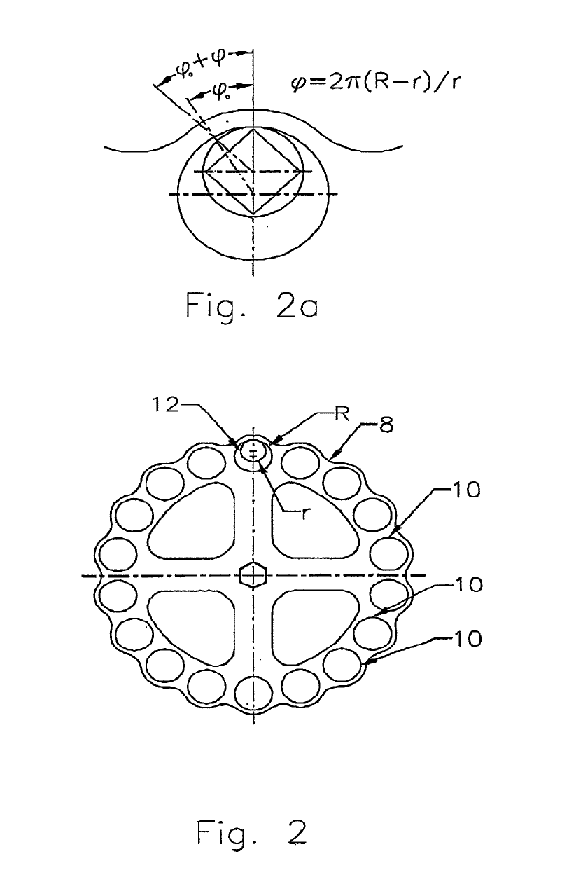

FIG. 1 generally illustrate the invention, which comprises of a means 2 for disposing the substrate 4 to be coated at an angle from an axis 6. In one embodiment as shown in FIG. 1, the means 2 for disposing the substrate 4 at an angle includes a plate 8 which may be circular as shown in FIG. 2 having a plurality of circular holes 10 with a radius R. The material or substrate 4 is received within one of the plurality of holes 10 at an acute angle. The substrate holder 12 has a circular cross section having a radius r in the vicinity where the substrate 4 intersects one of the plurality of holes 10 as shown in FIG. 2.

The substrate 4 is carried by a substrate holder 12 which roles within one of the holes 10.

Since the substrate 4 is disposed at an angle the substrate 4 will have a vertical force V and horizontal H for as shown in FIG. 1. The horizontal force H exerts the friction causing the tool holder 12 to roll inside the opening 10. As the disc 8 revolves the substrate inside the substrate holder 12 will roll within the hole 10 contacting the side of the hole 10 as it rotates along its own axis so as to expose different portions of the substrate 4 to the plasma.

FIG. 2a illustrates that for one turn of axis 6a, the substrate 4 rotates on angle Ψ=2nr/R relative the axis 6a. The substrate holder 12 must be cylindrical. Although the drawings generally illustrate a round substrate 4, the invention is not limited to a round substrate as other cross sectional shapes may be utilized. For example FIG. 2a shows a substrate having a square cross section.

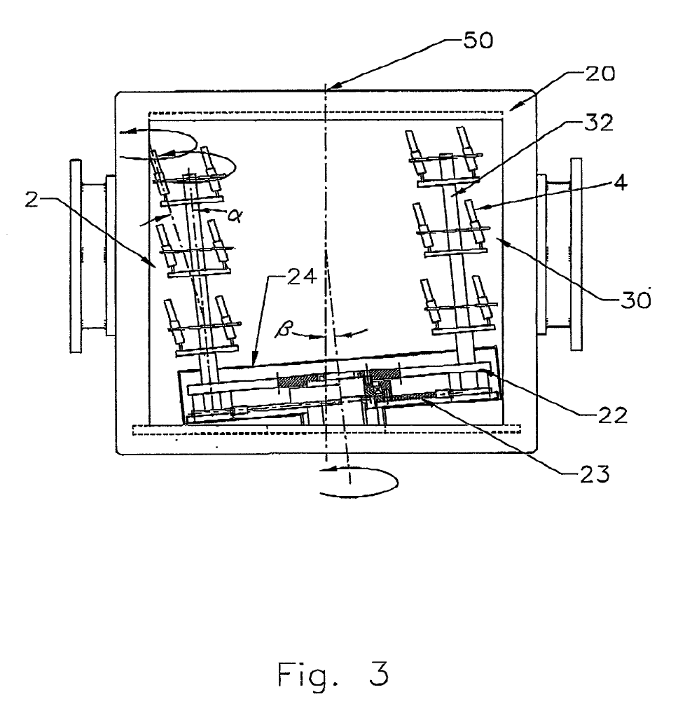

FIG. 3 illustrates the invention where 20 illustrates a vacuum chamber having a rotatable table 22 disposed therein. The table 22 has an upper component (shield), which is adapted to place the upper surface of the table at an angle relative to the horizontal. The upper portion 24 of the table includes a plurality of satellites 30, supported by stem 32, each stem being disposed normal to the upper surface 24. Each of the stems 32 are rotated relative the table 22 by means of gears 23 or the like as shown in FIG. 3.

Accordingly as the table 22 rotates about the vertical axis 50 within the vacuum chamber 20 plasma or vaporized material (not shown) are introduced in the vacuum chamber by chemical or physical means, and coat the substrate 4 in the manner well known to those persons skilled in the art. As the table revolves about axis 50 the substrates to be coated 4 are rotated along its own axis within the plurality of holes 10 due to the action of gravity in a manner which is simple and efficient when compared to substrate holders of the prior art.

In the examples shown in FIG. 3 the table 22 includes an upper surface 24 which may be disposed at an acute angle relative to the horizons or lower portion of chamber 20.

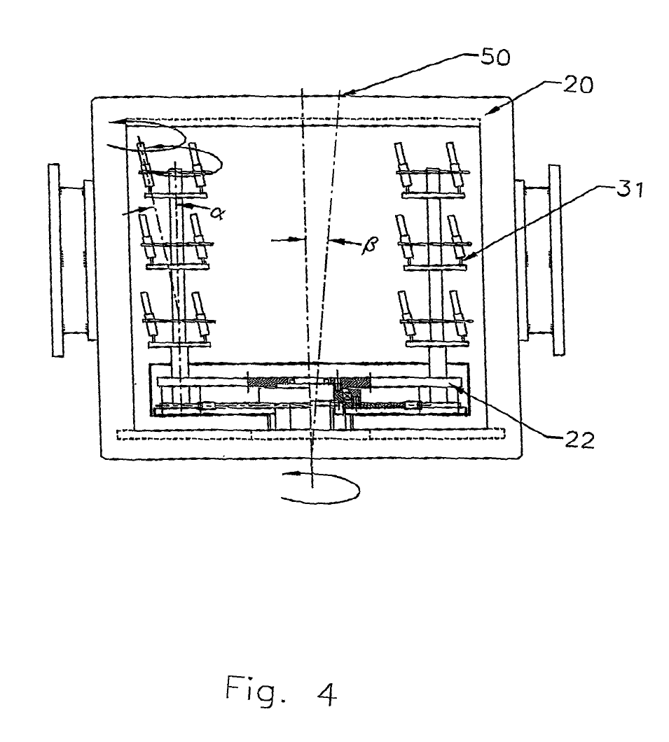

FIG. 4 illustrates another embodiment of the invention where the upper portion of the table 22 is fixed while the vacuum chamber 20 is disposed at an acute angle. The stems 32 are secured to the tabletop 24 at a normal angle and the table rotated in the normal fashion. However since the chamber 20 and hence the table 22 are disposed at an angle, the substrates 4 will rotate within the substrate holders in the fashion illustrated in FIG. 2(a) due to the vertical V and horizontal H forces shown in FIG. 1.

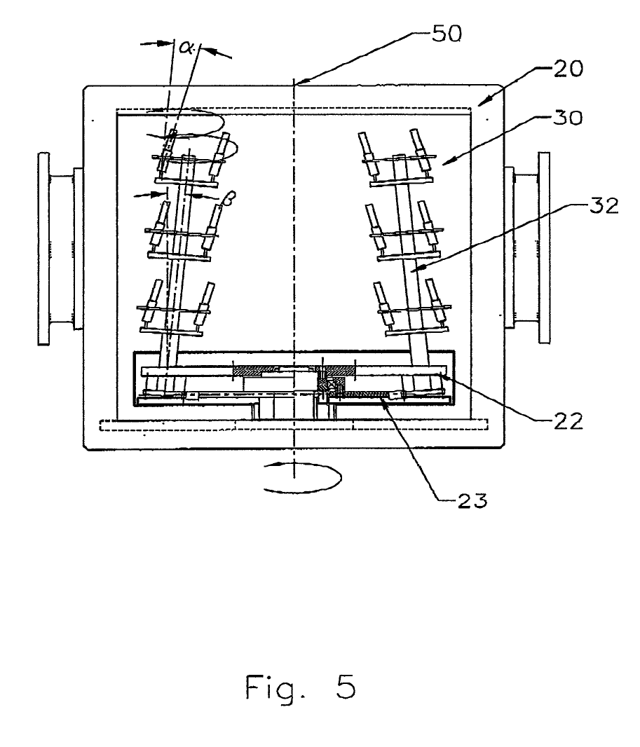

FIG. 5 illustrates another embodiment of the invention whereby the satellites 30 are carried by a plurality of stems 32 each of which are disposed inwardly at an acute angle towards the axis of rotation 5O and the stems 32 are rotated relative the table by gears 23 so as to impart relative motion between the substrates 4 and the holes 10 of satellite 30.

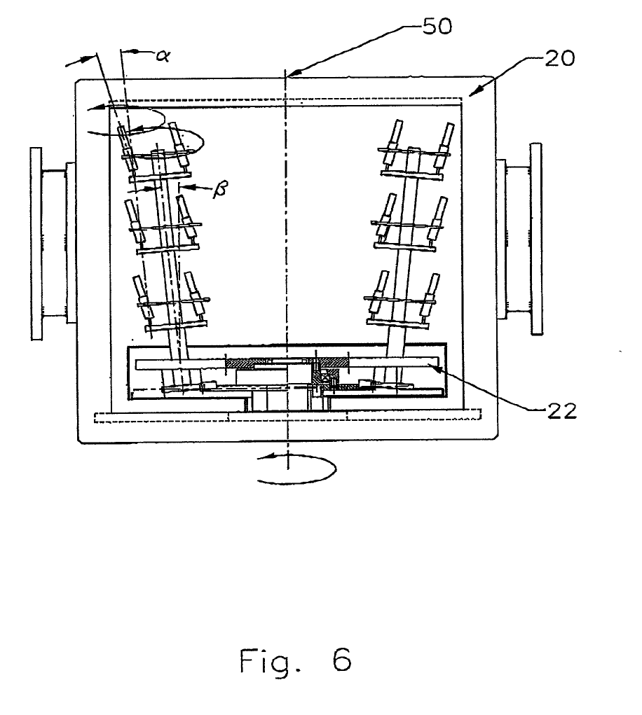

FIG. 6 illustrates another embodiment of the invention where the satellites 30 each are disposed at an acute angle outwardly of the axis of rotation 60, and the stems 32 each rotated by a gear within the table.

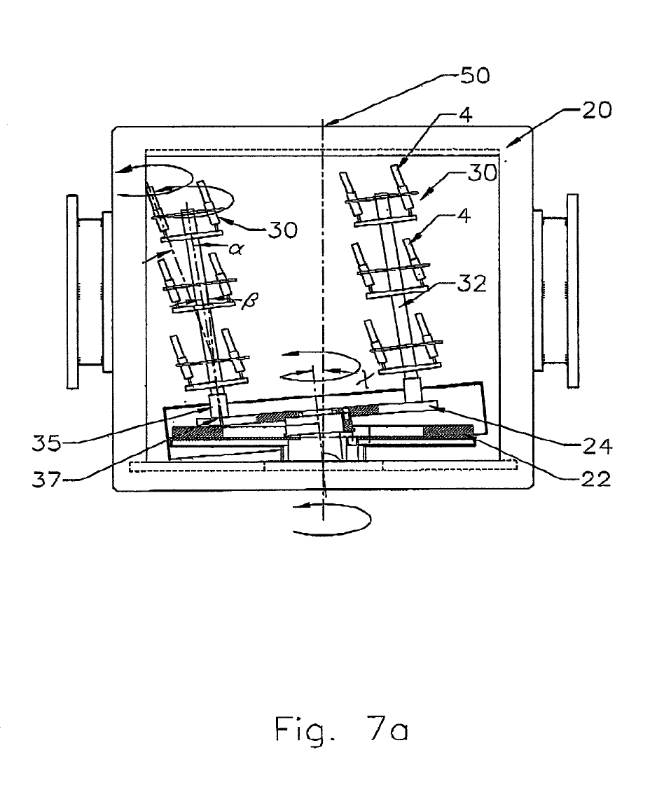

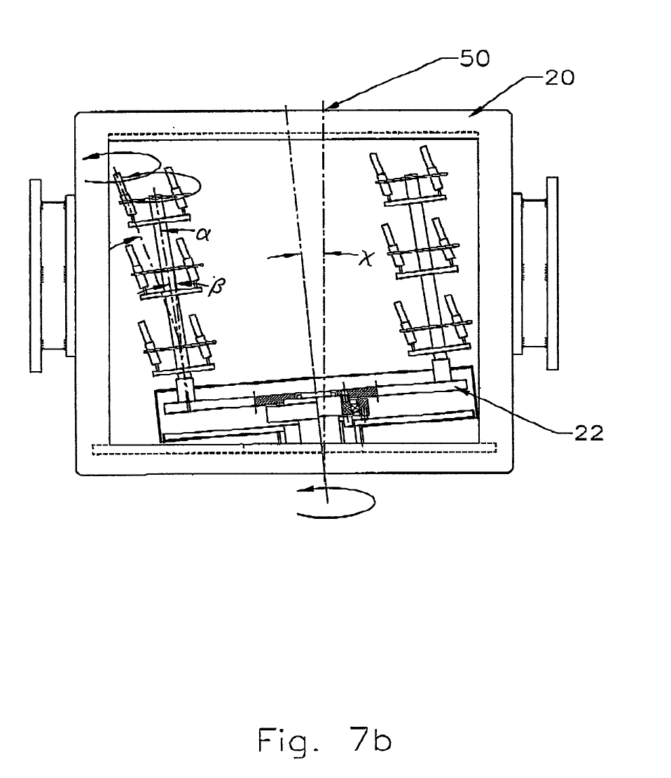

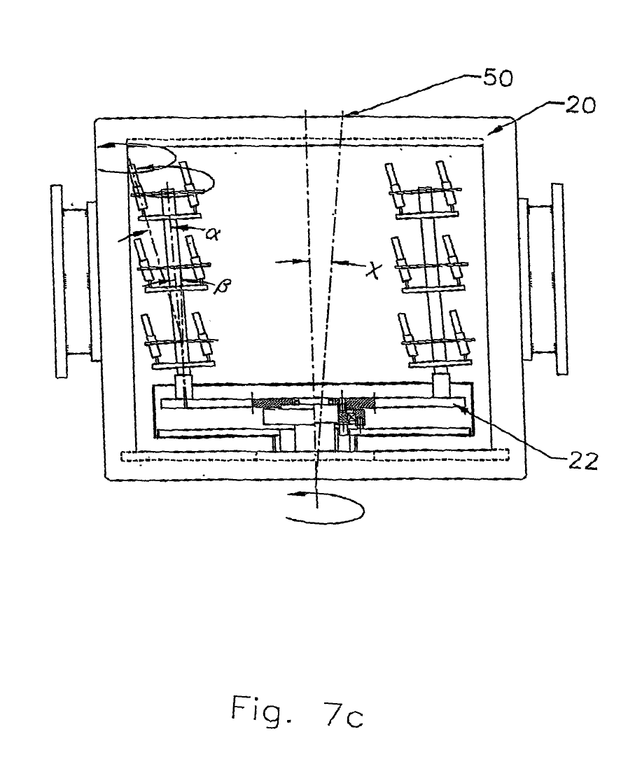

FIG. 7a illustrates another embodiment of the invention whereby there are no gears 23 to rotate the stems 32 as shown in FIG. 3, but the stems 32 rotate according to the same principles as shown in FIG. 1 for the substrate 4 since each stem 32 includes at the bottom portion a hollow sleeve 35 to receive a pin 37. As the table rotates each stem 32 which is disposed from the vertical by angle β (beta) will rotate along an axis B from the vertical and each substrate 4 in substrate holder 30 is disposed at an angle α (alpha). As the table 22 rotates each tool 4 will rotate in the holes 10 of satellite 30 and each stem will rotate about pin 37.

Therefore the stem will rotate about pin 37 much like the rotation of the substrate 4 about pin 60 in FIG. 1.

FIG. 7b is similar to the operation as shown in FIG. 7a, except the entire portion of the table is inclined and not just the upper portion 24. Similar sleeves 35 and pins 37 are used.

FIG. 7c is similar to FIG. 7a except the entire chamber is inclined.

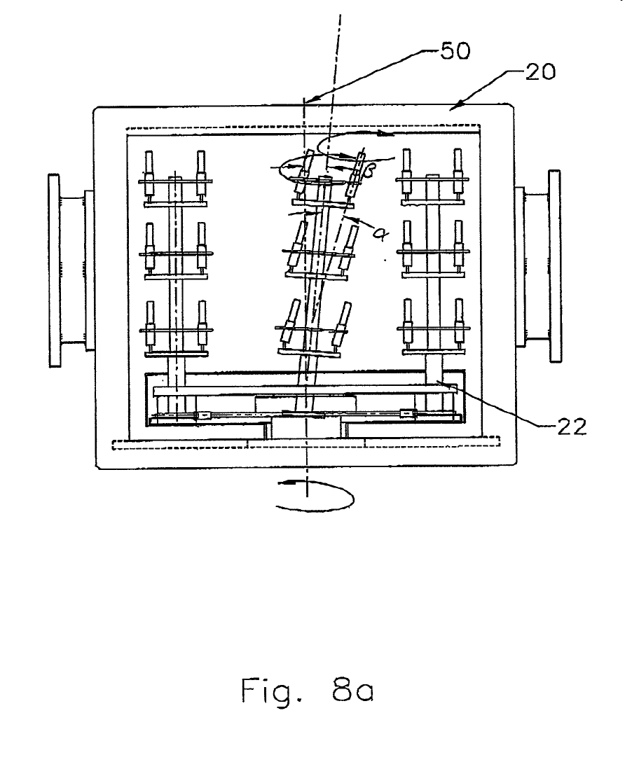

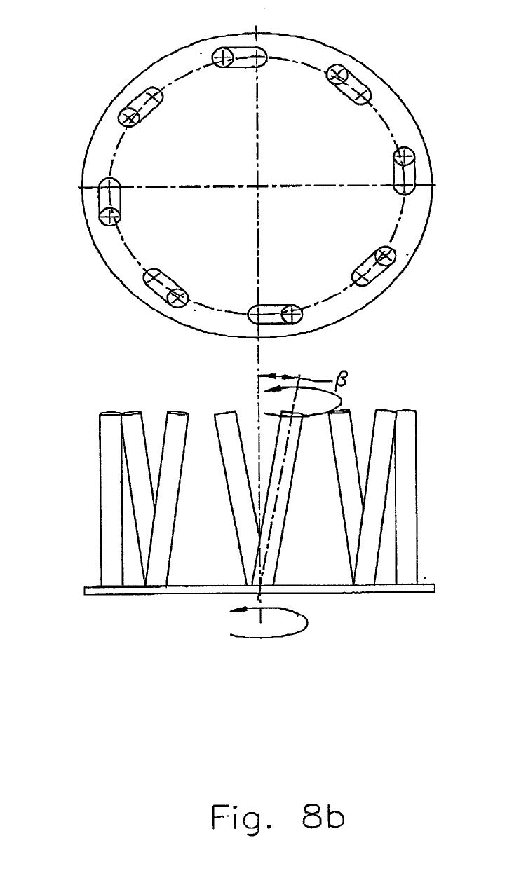

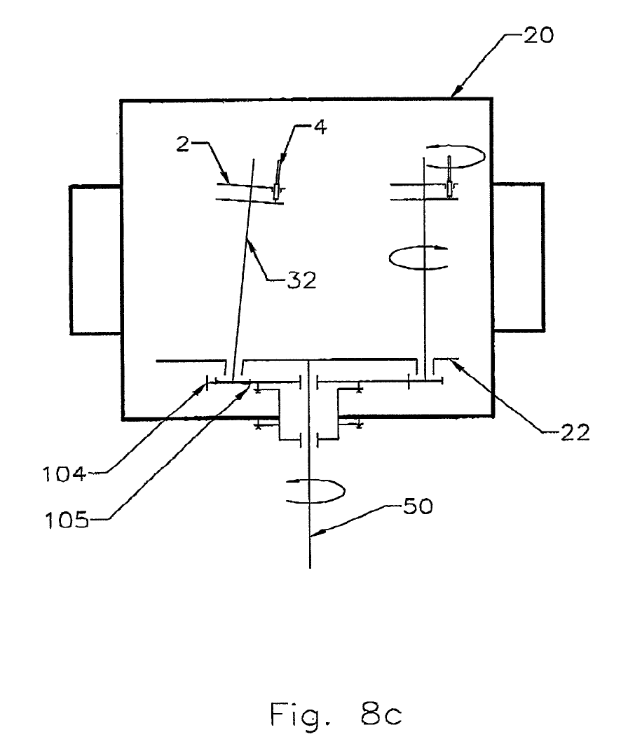

FIGS. 8(a), (b) and (c) illustrate another embodiment of the invention whereby each of the satellites 30 are disposed along a common radius from the axis but lean towards one another at an acute angle as illustrated in FIG. 8.

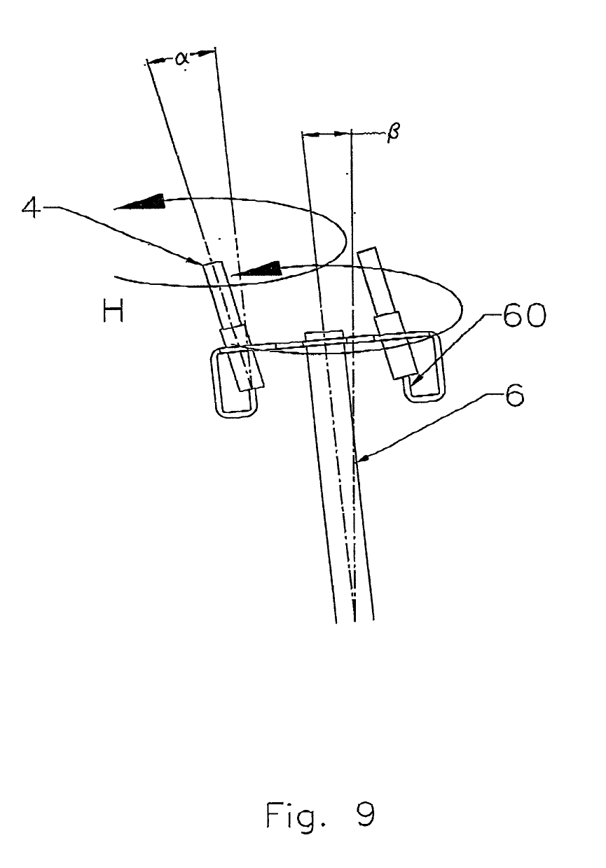

FIG. 9 is another embodiment of the invention, where there is no disc but the holes are made from wire and the same wires hold the substrate holder 12. In other words the end of the wire 60 which contacts the bottom of substrate holder 12 acts like the pin at the sides of the wire define the hole 10.

It will be noted from the embodiments described above that there are no bearings or gears that are utilized to drive the multileveled substrate holders 12 which adds to the simplicity of the design.

Furthermore depending on the configuration, weight and size of the material or substrate 4 to be coated various optimal and acute angles will be utilized to produce efficient rotation and exposure to plasma of the substrates during coating. It has been found that so long as the angle is acute good coating results have been produced. In other words the acute angle will generally fall within the range of more than 0° and less than 90° . In other embodiments it has been found that an acute angle of 5 to 10 degrees produces good results. Furthermore an acute angle of 7 degrees has been very useful in producing improved coated results.

The following general formula is useful to choose a relative rotational speed of the substrate holder 12 on its axis. This formula is based on the assumption that the substrate holder 12 does not slide relative the holes 10 but rather rotate there along. This assumption generally holds for contacting surfaces in high vacuum. In this case for every revolution of the satellite 30 or plate 8 about the stem axis. The substrate holder 12 will rotate inside of the opening 10 on angle Ψ (FIG. 2a)

Ψ=2n(R−r)/r

Where:

R—Radius of opening 10

r—Maximum Radius of the substrate holder 12

The substrate 4 makes one revolution relative to is axis

2n/Ψ=n° revolutions of satellite.

This n° revolutions of satellite is 2n/2n(R−r)/r=r/(R−r)

Accordingly:

n°=r/(R−r) number of rotation of the satellite 30 for one revolution of substarte holder 12 relative to its axis.

The configuration as shown in FIG. 3 is particularly useful as the acute angle may be adjusted to an optimal angle in an efficient manner.

Moreover the means 2 for disposing the substrate 4 at an acute angle as shown in FIGS. 1 and 2 also include in one embodiment an anchoring pin 60 which may be pointed so as to improve the rotational characteristics of the substrate 4 to be coated.

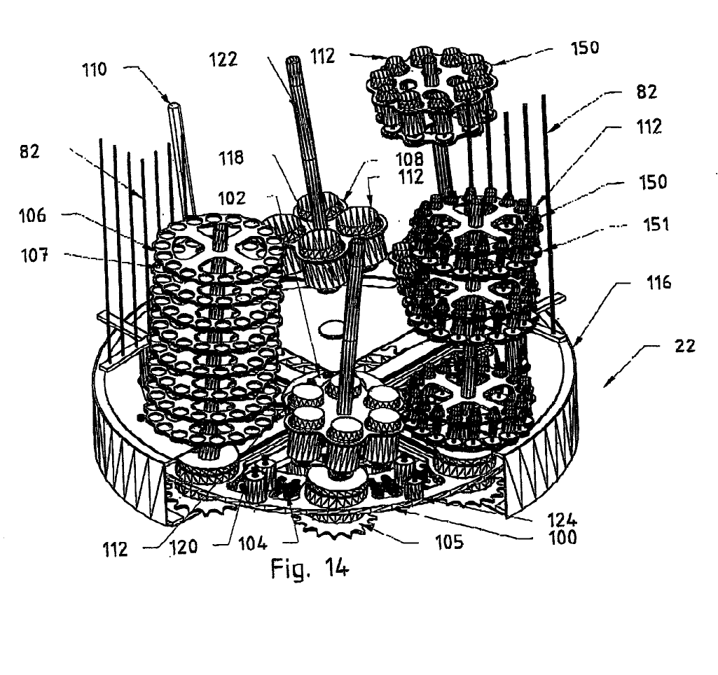

Although the invention has been described in relation to a satellite 30 as shown in FIGS. 1 and 2 other configurations of substrate holders may be utilized as shown for example in FIG. 14 which may consist of receptacles or the substrate holders 112 for receiving the substrate 4 at an acute angle and providing for rotational movement therebetween.

Furthermore other arrangements of rotating tables may be utilized as shown in FIGS. 10 and 11 where the materials to be coated are not rotated relative the substrate holder 30 but are held by very light tool holders to minimize the heat transfer from the substrate to the substrate holder, and table structure. In other words, the embodiment shown in FIGS. 10 and 11 are an improvement over the Balzers tool holders, which are massive heat sinks. FIG. 10 illustrates a substrate holder which consists of a relatively thin disc 80 which is bent at 82 and 84 so as to hold the substrate 4 at an angle to the vertical. Since the substrate holder 80 is very thin it act as a minimal heat sink. Furthermore other arrangements can be produced as shown in FIG. 11 whereby the substrate holder 80 includes thin wires 86 used to support the substrate 4 at an angle.

FIG. 12 illustrates yet another embodiment of the invention. Each of the satellites 30 holding the tools 4 can turn and carry a adaptor 5 each of which carry very small substrates 7 such as for example drills for PCB board drilling.

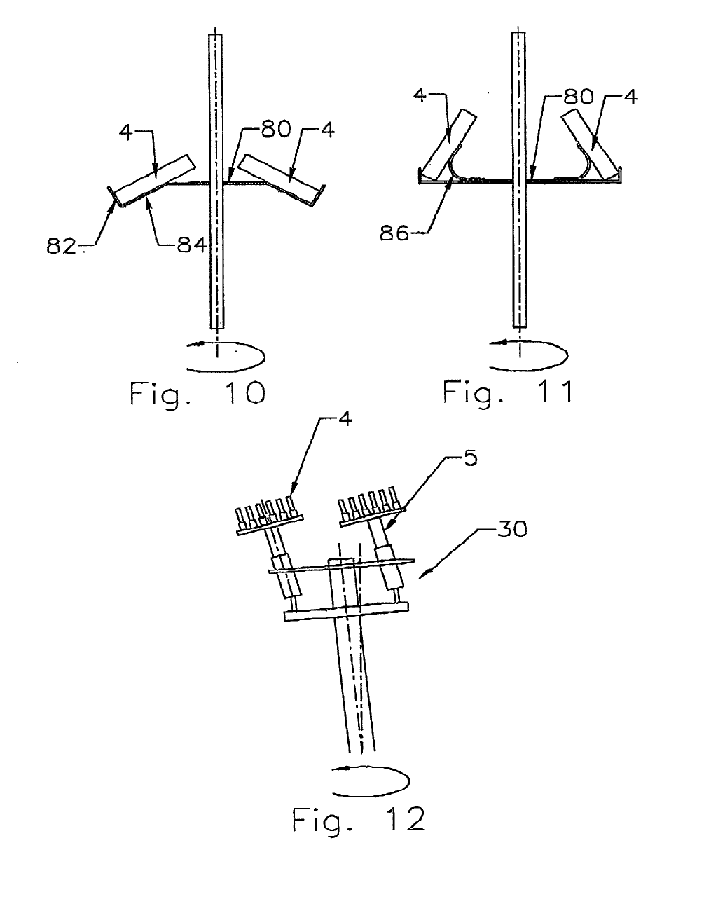

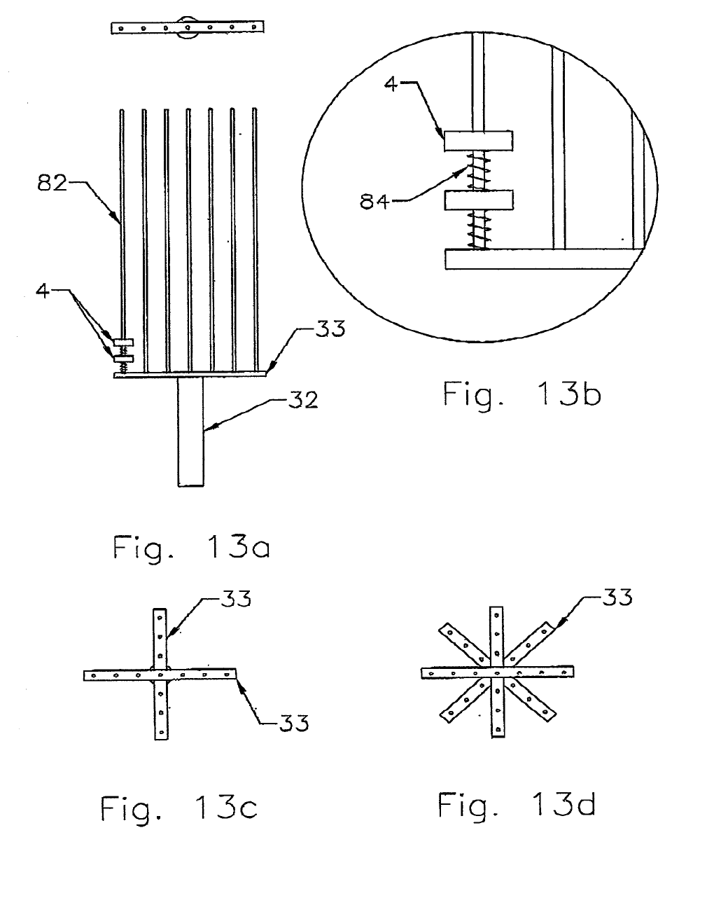

FIG. 13(a) illustrates yet another embodiment of a substrate holder, which comprises of a fork arrangement 82. In particular the substrate holder 82 comprises of a stem body 32 that can be secured to the table 22 in the manner previously described in the various embodiments. The fork member 82 has a support member 33 having a plurality of fingers or forks 82 extending therefrom. Each of the forks or fingers 82 are adapted to receive a tool insert 4 which has a hole therethrough. A plurality of tool inserts 4 may be stacked and spaced from one another on each of the fingers 82 as illustrated in FIGS. 13(a) and (b). The tool inserts 4 are separated from one another by means of a plurality of spacing means 84 which can comprise in one embodiment, a spring which separates the tool inserts 4 from one another The separating means 84 may comprise of a variety of structures and provides minimal heat sink.

Accordingly as the table 22 rotates the stem 32 will also rotate as described above causing the fork arrangement 82 to rotate about the axis of stem 32 as previously described. Accordingly the tool inserts 4 will rotate within the confines of the chamber 20 thereby exposing the tool inserts 4 uniformly within the plasma. Furthermore depending on the size and weight of the tool inserts 4 as well as the configuration of the spring spacing means 84 it is also possible that the tool inserts 4 may rotate about the axis of the hole therethrough through the fingers 82. In another arrangement the weight of the tool inserts 4 may cause sufficient frictional force in the spring 84 to prevent relative rotation of each of the tool inserts 4 about each finger 82 although the rotation of the stem 32 within the confines of the chamber 20 will be sufficient to ensure improved coating characteristics as shall be hereinafter described.

FIG. 13(c) illustrates another embodiment of the invention whereby two intersecting support members 33 are utilized so as to increase the density of the tools 4 to be coated.

Moreover FIG. 13(d) illustrates yet another embodiment of the invention whereby four intersecting support members 33 are utilized to once again further increase the density of the tools 4 to he coated.

FIG. 14 illustrates a partial broken up sectional perspective view illustrating in more detail an arrangement which may be found in FIGS. 8(a) and (b).

In particular FIG. 14 illustrates the horizontal table 22 within the chamber 20.

The horizontal table 22 includes a support plate 100 which supports the various components to be described herein. The table 22 includes a relatively large stationary gear 104. The plate 100 is connected to a central motor driven shaft 160. The plate 100 is adapted to rotate each of the smaller gears 105 in a planetary motion around the stationary gear 104. More specifically as shown in FIG. 16, the smaller gears 105 are operably connected to the drive shafts 136 which are slotted at the top thereof so as to receive for example the bottom portion of the stem 32 as shown in FIG. 18. More specifically the bottom part of stem 32 is hollow and includes a shaft 33 that extends through the hollowed out boom portion of the stem 32 which is adapted to receive the drive shaft 136 in the manner whereby the shaft 33 will engage through the slotted top portion of the drive shaft 136 so as to impart rotational movement thereabout as previously described.

FIG. 14 illustrates the various embodiments of substrate holders 112 and can consist of the fork arrangement 82 as previously described.

Moreover FIG. 16 illustrates that axles 110 may be utilized to engage the drive shafts 136 as previously described. The axles 110 may be adapted to receive a plurality of spacer tubes 122.

In another arrangement the axles 110 may be adapted to receive a plurality of stacked plates 106 which are separated from one another by spacer tubes 122, The spaced stacked plates 106 are similar to disc 8 as previously discussed except that each plate 106 includes a circular recess or depression 107 rather than the hole therethrough as shown in the previous figures. Each of the recesses 107 are adapted to receive circular substrates which have a smaller radius than the radius of the recesses so as to permit the circular substrates 4 to rotate within each of the recesses 107 in the manner as described in relation to FIG. 2(a). Each of the plates 106 are separated from one another by spacer tubes 122 so as provide a relatively dense structure capable of holding a plurality of many circular substrates 4 for coating.

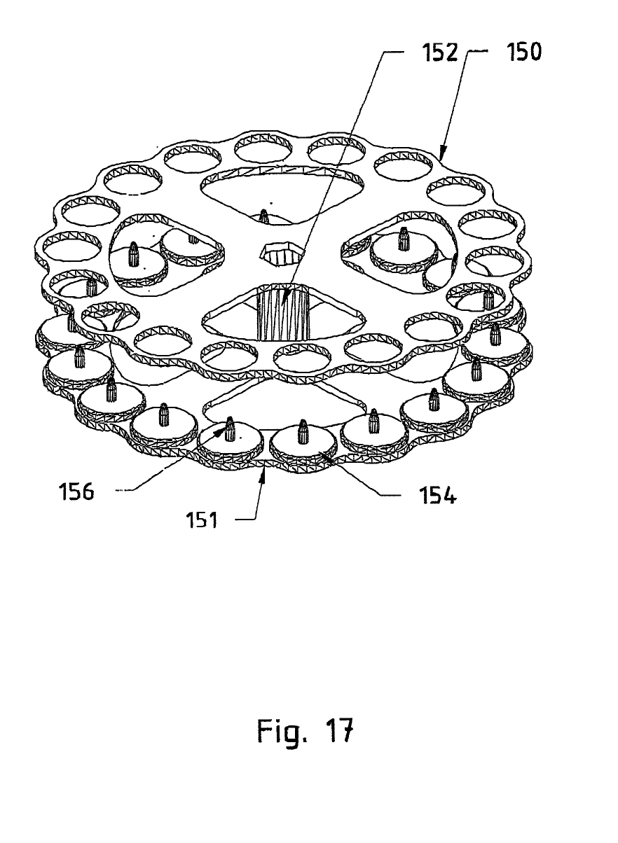

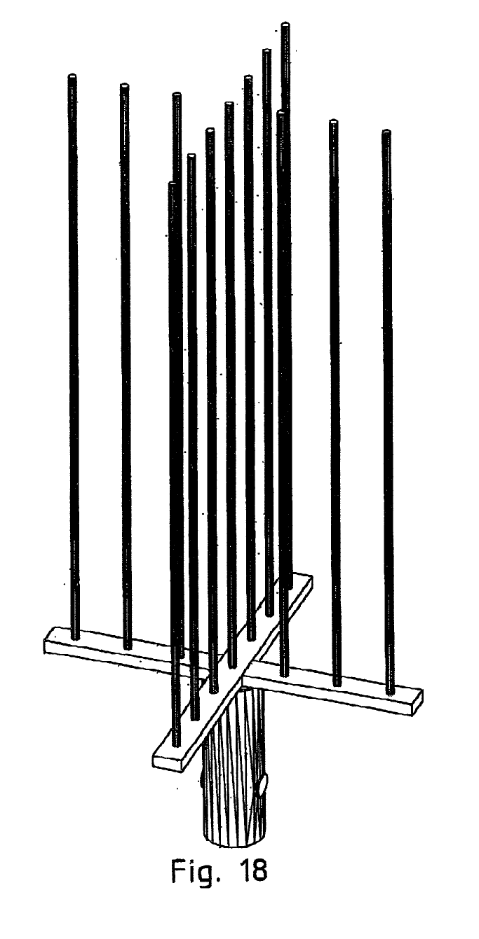

Moreover the substrate holders 32 can comprise of a bottom satellite plate 161 and top satellite plate 150 which are separated from one another by spacer tube 152 as illustrated in FIG. 17. As can be seen in FIG. 17, each of the top and bottom satellite plates 150 and 151 include holes 153 which are configured to drivingly engage the cross-section of the axle 110, The bottom satellite plate 151 includes a plurality of pin support plates or bushings 154 each of which include a pin 156 which is adapted to substantially axially align with the holes 10 of the top satellite plates 150. The top satellite plate 150 and bottom satellite plate 151 define substrate support means 32 as well as a satellite structure. Each of the satellites can be stacked one upon the other by means of spacer tubes 122. The size of the spacer tubes may be selected so as to separate each of the satellite means from one another in a close or further apart selected position designed to maximize the number of substrates 4 to be coated.

Moreover the top and bottom satellite plates 150 and 161 can hold a plurality of substrate holders 112. The substrate holders 112 consists of a cup shaped structure adapted to receive a substrate there within. In this arrangement the radius of the substrate holder will be selected at r and the radius of the hole 10 is R. The top of the substrate holder 112 is tapered or angled to present a sharp line of coating rather then a shadow.

The satellite structure illustrated in FIG. 17 can comprise of any suitable materials which can be selected to withstand the environment of the chamber 20. In one embodiment the pins 156 can comprise of a material that must conduct electricity yet are wear resistant and withstand high temperature. One such material can consist of tungsten carbide. Furthermore the top satellite plates and bottom satellite plates 150 and 151 must similarly conduct electricity and withstand high temperature environments and can comprise of stainless steel or Inconel.

It is apparent from FIG. 16 that the table plate 100 also includes a plurality of electrical insulators 124 which can comprise of a variety of materials including ceramic. The function of the electrical insulators 124 is to support the shields 116 and 126 as shown on FIG. 14 with the intent to eliminate bias potential on the shield 116. The shield 116 inhibits the hard coating material from being deposited onto the moving mechanisms located within the rotating table, such as the bearings and the gears. Furthermore the shield 116 acts as a heat shield and plasma shield.

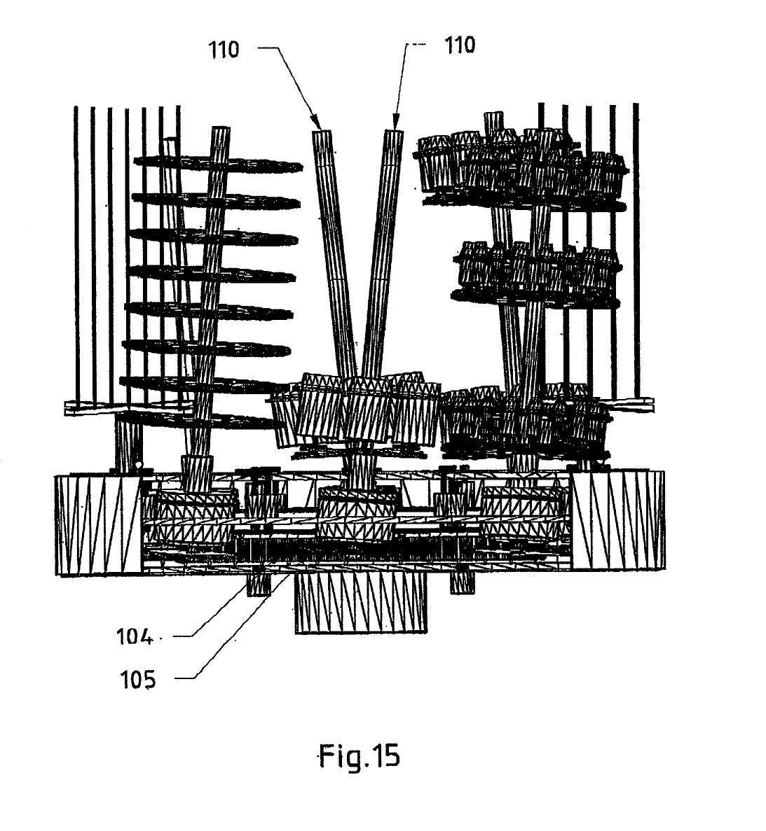

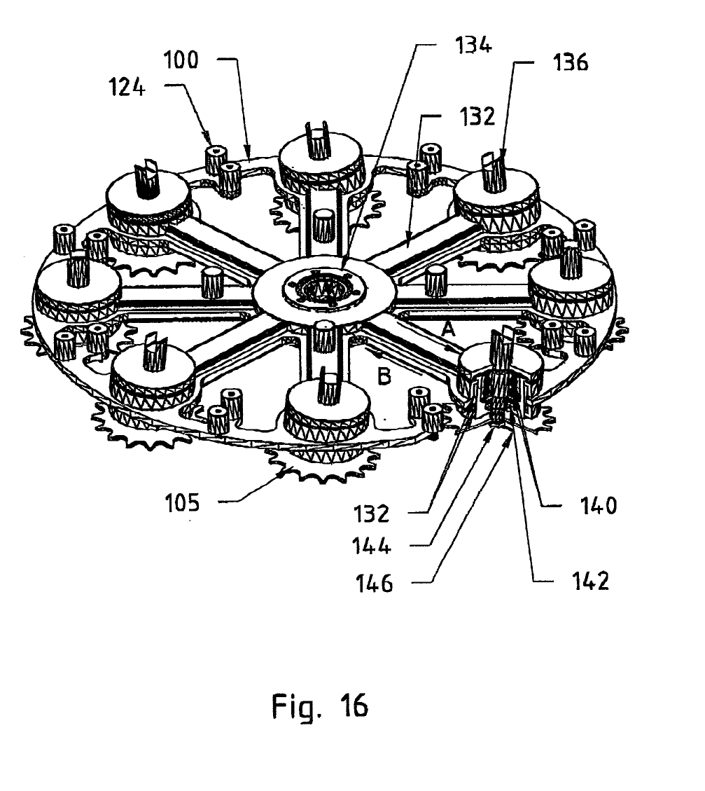

Moreover it is apparent from FIG. 15 that the main stationary gear 104 has a generally larger thickness than the thickness of each of the planetary gears 105. Furthermore the axis of rotation of each of the planetary gears 105 are disposed at an acute angle relative to the vertical while the axis of rotation of the stationary gear 104 is generally vertically disposed. Accordingly the thickness of the stationary gear 104 must be selected so as to provide positive engagement of each of the teeth of the planetary gears 105. Furthermore since the axis of rotation of the planetary gears 105 are disposed at an acute angle relative to the stationary gear 104 the convolute shapes of the tooth flanks of the planetary gears 105 are shaped so as to provide good positive engagement with the stationary gear 104

Moreover each of the planetary gears 105 is operably connected to bearings 140 as shown in FIGS. 16. For example the bearings 140 can consist of a ball bearing as well as thrust bearings 142 which are designed to withstand the weight from above. Bearings are not generally used in thermo deposition, cathode sputtering or chemical vapor deposition for coating substrate materials since the bearings will generally seize and not rotate due to the high temperature operation in the chamber. More specifically the various components of the bearings are usually made from different materials which tend to expand at different rates when exposed to the operating environment of the chamber 20 by causing the bearing structure to seize and inhibit rotation.

FIG. 8c is a schematic view of FIG. 15 showing rotation of table 22, engagement of stationary gear 104 with planetary gears 105 inclined as discussed.

The structure illustrated in FIG. 16 shows the use of cooling means to cool the bearing structures 140 and 142 thereby eliminating seizing experienced in the prior art. More specifically the support plate 100 includes a plurality of channels 132 which are disposed in a general spoke like fashion connecting each of the bearing means 140 and 142 with a central hub structure 134.

As illustrated in FIG. 16, cooling means such as water travels up through the hub 134 and flows outwardly through channels 132 in the direction of arrow A and communicates with the bearing means 140 and 142 through means of water passages or channels 132 so as to carry away excess heat back down through the channels 132 and back down through the hub 134 in direction B in a manner to be more fully described herein. Water is generally used as the cooling means flowing through the channels 132 although other suitable fluids may be utilized. Generally speaking the volume and rate of flow of the water cooling means is selected so that the bearings operate at a temperature that eliminates seizing. Goods results have been experienced by regulating the flow of water so as to operate the bearings at a temperature less than 100° C. FIG. 16 furthermore illustrates the tool driving means consisting of the planetary gear 105 Which is operably connected to the bushings 140 and 142 by means of the shafts 136 which is adapted to receive a nut 144 at one end thereof as well as cotter pin 146 so as to prevent the nut from slipping of the drive shaft 136. The drive means also includes the cooling means consisting of the channels 132 as previously described.

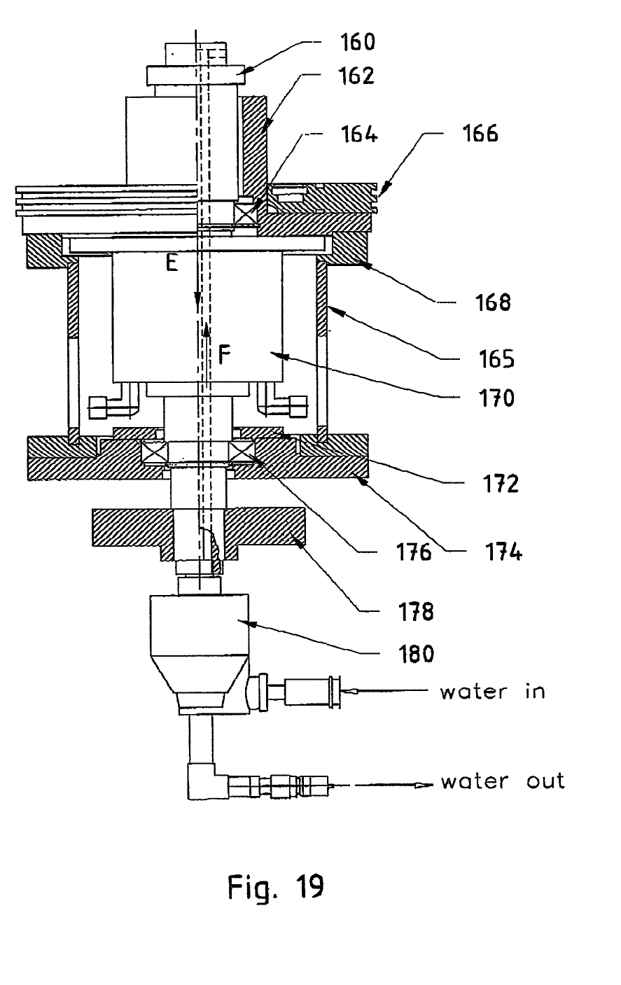

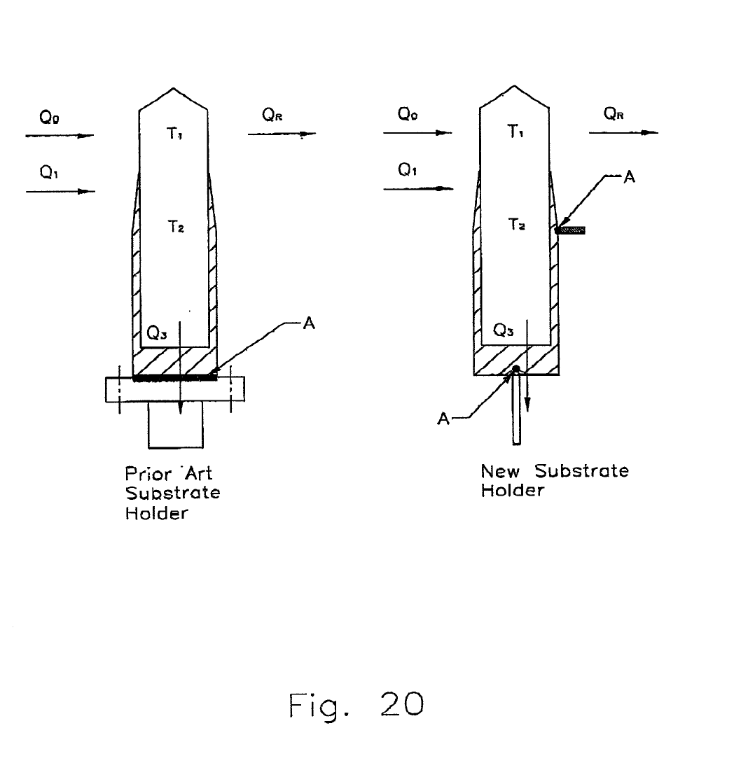

FIG. 16 also illustrates the top of hub 134, which includes appropriate water channels that communicate with the water channels 132 previously described. The carrier plate 100 is adapted to engage the central shaft driving means illustrated in FIG. 19. The central driving shaft 160 is operably connected to the carrier plate 100 in a manner well known to those persons skilled in the art. The top part of shaft 160 has a water copper seal which is adapted to sealingly engage the hub 134. The shaft 160 includes a support 162 that is adapted to support the stationary gear 104. Electrical insulation 166 such as Teflon is utilized between grounded chamber 20 and stationary gear support 162. A support tube 165 is included which houses ferro fluidic feed through high vacuum rotating joint 170 which has a water inlet and water outlet to cool the rotating joint 170 therein. The tube 165 connects the support 168 to cover 172 and bearing hut 174 which is adapted to carry radial load thrust bearing 176 in a manner well known to those persons skilled in the art. A drive wheel or pulley 178 is utilized to rotate the shaft 160. Furthermore a rotating water joint 180 is utilized which is adapted to receive water in. The water which flows into the rotating water joint 180 communicates with a central passage through shaft 160 as illustrated by arrow E feeding water into the channels 132 for cooling of the bearings 140 and 142 described previously. The water then carries excess heat away from the bearings 141 and 142 back through the shaft 160 through a co-axial passageway F and out through the rotating water joint illustrated in FIG. 19.

The structure illustrated in FIG. 19 illustrates that the main bearings 176 are located outside of the vacuum chamber 20 and are lubricated.

The various embodiments described herein can be utilized to coat substrates 4 by utilzing any variety of substrate holders which are disposed at an acute angle causing rotation of the substrates 4 as the table rotates within the vacuum chamber 20 so as to more uniformly expose the substrates to the coating deposition material. Such structure minimizes the complicated gearing arrangements utilized in prior art tables. Furthermore such prior art structure creates a massive heat sink which makes it difficult to accurately control the surface temperature of the substrates 4 in a uniform fashion as it is being coated.

Furthermore it is difficult in prior art to agressively heat the substrates 4 being coated to a high enough temperature to provide for good quality coating since fixture tend to seize up at such higher temperatures.

For example good quality results have been observed by utilizing stainless steel fixtures at temperatures up to 700° C. as well as Inconel fixtures up to 1100° C. Such good results were observed using the fixtures or substrate holders 30 described herein. Generally speaking the substrate 4 are preheated Within the chamber 20 by heating means in a manner well know to those persons skilled in the art. For example if the substrates 4 are preheated to 500° C. and then subjected to coating by PVD of up to two hours in accordance with prior art methods it would not be unusual for such substrate 4 to drop in temperature from 500° C. to 350° C. in view of the large contact surface A between the substrate 4 and the zone of contact as illustrated in FIG. 20. However, when the substrate 4 is coated in accordance with the teachings of the invention described herein the same substrate may only experience a drop in temperature from 500° C. to 450° C. since the substrate 4 is essentially held at two points of contact A as illustrated in FIG. 20. Such two point contacts present a negligible heat sink as compared with the prior art. Accordingly better and more uniform coatings have been experienced.

Furthermore it was generally not feasible to obtain good oxide coatings of the alpha phase of aluminum oxides at 500° C. since temperatures of approximately 8000° C. must be utilized. At 800° C. the prior art fixtures tended to seize up.

The following example illustrates improved results over the prior art.

### EXAMPLES

The following seven samples illustrate that a substrate 4 of tungsten carbide (i.e. WC) was subjected to PVD plasma coating (in all instances by cathodic arc evaporation) of either titanium nitride TiN. Titanium Aluminum Nitride (TiAIN) or Titanium Aluminum Carbonitride (TiAICN). The various samples were subjected to coating either utilizing a prior art or conventional table of applicant's verses competitors as well as the new table of the invention described herein. The particular embodiment of the table utilized was that shown in FIG. 8. The coated substrates 4 were then subjected to a Micro Scratch Testing such as for example used by CSEM instruments where the instrument utilizes a generally sperhical diamond indenter having a stylus radius illustrated below. Generally speaking five scratches are performed with each indenter with a particular pressure being applied or load described below and having a scratch length in each case of 5 mm where the load rate is kept constant. The critical load is then measured to provide a scratch of a desired length. The spherical diamond intender were used with radii of 20, 60, 100 and 500 microns. Five scratches are performed for each indenter on each sample and the average value of critical load was calculated. The scratch length in each case is generally 5 mm and the load rate was kept constant for all measurements at 10N/min. Either two or three critical loads were determined for each sample type by optical microscopy inspection of the damaged area after scratching. In some cares the acoustic emission signal was used to confirm the measured values in a manner well known to those persons skilled in the art. The results are presented in the following table:

### EXAMPLES

| | | | | Stylus | Hardnes |
|---|---|---|---|---|---|
| | | Source, | Critical | radius | (load) |
| Coating | Substrate | Fixture | load [L] | [μm] | [GPa]([g]) |
| TiN | WC | Chessen, | 4.1 | 50 | 21(50) |
| | | conventional | | | |
| TiN | WC | Chessen, | 6.2 | 50 | 23(50) |
| | | new Table | | | |
| TiAIN | WC | Chessen, | 10.3 | 50 | 28.3(25) |
| | | conventional | | | |
| TiAIN | WC | Chessen, | 16.3 | 50 | 32.75(25) |
| | | new Table | | | |
| TiAICN | WC | Manufacturer | 3.6 | 100* | 21.5(50) |
| | | “B” | | | |
| TiAICN | WC | Chessen, | 4.2 | 50 | 28.0(25) |
| | | conventional | | | |
| TiAICN | WC | Chessen, | 9.0 | 50 | 34.0(25) |
| | | New Table | | | |

*For samples from “B” low load and smell stylus radius is not available because of the high surface roughness of the coating.
*All coatings at 2.5 microns thickness

As can be seen from the chart referred to above improved critical load, microhardness and adhesion characteristics have been observed by utilizing the method described herein.

Accordingly the invention described herein provides the following benefits:

1. Increased capacities are experienced in loading more substrates 4 to be coated because less space is utilized for the table fixture as compared with the prior art. In some cases 30 to 60% more loading is experienced.

2. Improved quality of coating is also experienced because of better thermal management of the substrate itself in view of:

(i) minimizing the heat sinks been the tool and the tool holder

(ii) maximizing temperature uniformity throughout the tool during coating.

3. More uniform transfer of heat during preheating and vapor deposition

4. Better adhesion

5. Better hardness properties compared to the prior art.

6. Reduced maintenace and cleaning requirements for the fixturing

7. Reduced Bias power requirements due to small surfaces and weight of the fixture.

8. Reduced set up times in production of PVD coatings due to universality of the modular table fixtures and possibility to accommodate mixed batches

Moreover the table fixture described herein can be used for combined processes such as plasma assisted CVD where the temperature may exceed 1000° C.

Furthermore the process described herein can utilize PVD and heat treating in one process. For example the substrate 4 may be coated as described above and thereafter the substrate subjected to annealing or other heat treating processes for exposing the coated substrate to 800° C. to 1100° C. where heat treatment occurs more evenly throughout the substrate in a quicker and more efficient fashion than disclosed in the prior at.

The improved thermal management described above decreases stresses imparted on the substrate and increased critical load values of the coatings as can be seen from the example described herein.

Various embodiments of the invention have now been described in detail. Since changes in and/or additions to the above-described best mode may be made without departing from the nature, spirit or scope of the invention, the invention is not to be limited to said details.

Although the preferred embodiment as well as the operation and use have been specifically described in relation to the drawings, it should be understood that variations in the preferred embodiment could be achieved by a person skilled in the trade without departing from the spirit of the invention as claimed herein:

1. Means for disposing a substrate to be treated in vacuum, at an acute angle relative to the axis of rotation so as to permit the substrate to roll relative to said means.

2. Means as claimed in claim 1 wherein treatments may include in particular coating, heat treatment, ion bombardement, ion implantation, ion etching and other

3. Means as claimed in claim 1 wherein said means for disposing said tool at an acute angle comprises a disc having a plurality of holes each of which holes are adapted to receive said tool for rotational movement therebetween.

4. Means as claimed in claim 2 wherein said tool rolls relative said holes due to the action of gravity.

5. A substrate holder adapted to be supported on a rotatable table in a vacuum chamber, said substrate holder including means for receiving material to be treated at an acute angle relative to the axis of rotation of said table and for relative rolling movement of said substrates relative said means.

6. A substrate holder as claimed in claim 1 wherein said substrate holder is disposed relative said table and said table is disposed at an acute angle from the horizontal.

7. A substrate holder as claimed in claim 4 wherein said table is horizontal and said substrate holders are disposed at an acute angle relative to said vertical.

8. A plurality of substrate holders each comprising a stem with spaced apart discs, each disc having a plurality of holes adapted for receiving a plurality of substrates at an acute angle for relative rotational movement therebetween.

9. A plurality of substrate holders as claimed in claim 7 wherein said substrate holders are disposed at an acute angle towards to said axis of said table.

10. A plurality of substrate holders as claimed in claim 7 wherein each said substrate holder is disposed at an acute angle disposed at an acute angle away from said axis of rotation of said table.

11. A plurality of substrate holders as claimed in claim 7 wherein said substrate holders are disposed along a common radius relative said axis of rotation of said table and each said substrate holder is disposed at an acute angle towards one another.

12. A table or a vacuum deposition chamber, said table supporting at least one substrate holder disposed at an acute angle relative to the axis of rotation of said table, so as to permit said substrate to rotate relative said holder.

13. A table as claimed in claim 11 wherein said table is water cooled and shielded.

14. A table as claimed in claim 12 wherein said table holder is connected to bushing means.

15. A table as claimed in claim 13 wherein said bushing means are water cooled.

16. A table as claimed in claim 14 wherein said substrate holder includes a system operably connected to said bushing means.

17. A table as claimed in claim 15 wherein said stem and substrate holder is rotationally connected to driven gear means.

18. A table as claimed in claim 16 wherein such table includes a stationary gear and planetary gears.

19. A table as claimed in claim 17 wherein said table includes water channels operably connected to said bushing means for cooling of said bushing means.

20. A table as claimed in claim 18 wherein said water channels connected to a hub.
